(19) United States
(12) Patent Application Publication
(10) Pub. No.: US 2015/0302710 A1
(43) Pub. Date: Oct. 22, 2015

(54) DYNAMIC VISION SENSORS AND MOTION RECOGNITION DEVICES INCLUDING THE SAME

(71) Applicant: Samsung Electronics Co., Ltd., Suwon-si (KR)

(72) Inventors: Hyun-Jong JIN, Gwacheon-si (KR); Yun-Hong Kim, Suwon-si (KR); Tae-Chan Kim, Yongin-si (KR)

(21) Appl. No.: 14/583,836

(22) Filed: Dec. 29, 2014

(30) Foreign Application Priority Data
Apr. 17, 2014 (KR) 10-2014-0045941

(51) Int. Cl. G08B 13/196; H04N 7/18

(52) U.S. Cl. CPC G08B 13/1961; H04N 7/183

(57) ABSTRACT

A dynamic vision sensor includes a sensing pixel array including a plurality of sensing pixels each detecting a change of light intensity to output an event by a unit of time-stamp and a control unit that controls the sensing pixel array. Here, each of the sensing pixels has an inclined N-polygon shape, where N is an even number greater than or equal to 4. In addition, each of the sensing pixels includes first sides extended in a first direction that stand opposite to each other in a second direction in a staggered form and second sides extended in the second direction that stand opposite to each other in the first direction in a staggered form, where the first direction is perpendicular to the second direction.

### CROSS-REFERENCE TO RELATED APPLICATION(S)

This application claims priority under 35 USC §119 to Korean Patent Application No. 10-2014-0045941, filed on Apr. 17, 2014 in the Korean Intellectual Property Office (KIPO), the contents of which are incorporated herein in its entirety by reference.

### BACKGROUND

According to mobile convergence, an electronic device (e.g., a smart phone, a smart pad, etc) includes various sensors that perform specific sensing functions. In particular, as a user interface that enables a user to control an electronic device without a user touch on the electronic device receives attention, the electronic device further includes a dynamic vision sensor that perform user motion recognition, user proximity detection, etc. Generally, the dynamic vision sensor detects a portion of the subject in which a motion occurs, and outputs events related thereto by a unit of time-stamp. Thus, the dynamic vision sensor includes a plurality of sensing pixels each detecting a change of light intensity to output an event related thereto. However, since each sensing pixel has a complex internal structure (e.g., includes more components compared to a unit pixel of a typical image sensor), it is difficult to increase resolution of the dynamic vision sensor having a limited size.

### SUMMARY

Some example embodiments provide a dynamic vision sensor having increased (or, improved) resolution while having a fixed (or, limited) size.

Some example embodiments provide a motion recognition device including the dynamic vision sensor.

According to an aspect of some embodiments, a dynamic vision sensor may include a sensing pixel array including a plurality of sensing pixels each detecting a change of light intensity to output an event by a unit of time-stamp and a control unit configured to control the sensing pixel array. Here, each of the sensing pixels may have an inclined N-polygon shape, where N is an even number greater than or equal to 4. In addition, the each of the sensing pixels may include first sides extended in a first direction that stand opposite to each other in a second direction in a staggered form and second sides extended in the second direction that stand opposite to each other in the first direction in a staggered form, where the first direction is perpendicular to the second direction.

In some embodiments, the event may include at least one selected among time information related to when the change of light intensity occurs and location information related to where the change of light intensity occurs.

In some embodiments, an event detection distance in the first direction may correspond to a distance between the second sides of adjacent sensing pixels. In addition, an event detection distance in the second direction may correspond to a distance between the first sides of the adjacent sensing pixels.

In some embodiments, the sensing pixels may be repetitively arranged on the sensing pixel array in the first direction and the second direction in a staggered form.

In some embodiments, the first sides may be point-symmetrical to each other with respect to a center of the inclined N-polygon shape in the each of the sensing pixels. In addition, the second sides may be point-symmetrical to each other with respect to the center of the inclined N-polygon shape in the each of the sensing pixels.

In some embodiments, a light receiving element of the each of the sensing pixels may be located in a center region that includes the center of the inclined N-polygon shape, and a location of the light receiving element in the inclined N-polygon shape may be the same for all of the sensing pixels.

In some embodiments, a light receiving element of the each of the sensing pixels may be located in a center region that includes the center of the inclined N-polygon shape, and a location of the light receiving element in the inclined N-polygon shape may differ according to the sensing pixels.

In some embodiments, a light receiving element of the each of the sensing pixels may be located near the first sides or near the second sides, and a location of the light receiving element in the inclined N-polygon shape may be the same for all of the sensing pixels.

In some embodiments, a light receiving element of the each of the sensing pixels may be located near the first sides or near the second sides, and a location of the light receiving element in the inclined N-polygon shape may differ according to the sensing pixels.

According to some embodiments, a motion recognition device may include a sensing pixel array including a plurality of sensing pixels each detecting a change of light intensity to output an event by a unit of time-stamp, a control unit configured to control the sensing pixel array, and a motion information generating unit configured to generate motion information by analyzing a motion region based on the event. Here, each of the sensing pixels may have an inclined N-polygon shape, where N is an even number greater than or equal to 4. In addition, the each of the sensing pixels may include first sides extended in a first direction that stand opposite to each other in a second direction in a staggered form and second sides extended in the second direction that stand opposite to each other in the first direction in a staggered form, where the first direction is perpendicular to the second direction.

In some embodiments, the event may include at least one selected among time information related to when the change of light intensity occurs and location information related to where the change of light intensity occurs.

In some embodiments, an event detection distance in the first direction may correspond to a distance between the second sides of adjacent sensing pixels. In addition, an event detection distance in the second direction may correspond to a distance between the first sides of the adjacent sensing pixels.

In some embodiments, the motion information generating unit may obtain a first motion vector related to a first direction motion and a second motion vector related to a second direction motion by analyzing the motion region.

In some embodiments, the motion information generating unit may obtain a third motion vector related to a third direction motion between the first direction motion and the second direction motion based on a vector operation between the first motion vector and the second motion vector.

In some embodiments, the motion information generating unit may generate the motion information corresponding to a user motion by analyzing the first motion vector, the second motion vector, and the third motion vector using a predetermined algorithm.

Therefore, a dynamic vision sensor according to some embodiments may have increased resolution while having a fixed size by including a plurality of sensing pixels that are repetitively arranged on a sensing pixel array in first and second directions in a staggered form, where the first direction (e.g., X-axis direction) is perpendicular to the second direction (e.g., Y-axis direction). Here, each sensing pixel may have an inclined N-polygon shape, where N is an even number greater than or equal to 4. Moreover, each sensing pixel may include first sides extended in the first direction that stand opposite to each other in the second direction in a staggered form and second sides extended in the second direction that stand opposite to each other in the first direction in a staggered form.

In addition, a motion recognition device according to some embodiments may accurately recognize a user motion by including the dynamic vision sensor.

Some embodiments include a dynamic vision sensor that includes a sensing pixel array including multiple sensing pixels. Ones of the sensing pixels may be configured to detect a change of light intensity and to output an event responsive to detecting the change of light intensity. A control unit may control the sensing pixel array. Some embodiments provide that ones of the sensing pixels have an inclined N-polygon shape, where N is an even number greater than or equal to 4 and that ones of the sensing pixels include first sides extended in a first direction that stand opposite to each other in a second direction in a staggered form and second sides extended in the second direction that stand opposite to each other in the first direction in a staggered form, the first direction being perpendicular to the second direction.

In some embodiments, the detected change comprises a rate of change event corresponding to the detected change over a time interval unit. Some embodiments provide that the at least one event is selected from time information and location information. The time information corresponds to when the change of light intensity occurs and the location information corresponds to where the change of light intensity occurs.

Some embodiments provide that an event detection distance in the first direction corresponds to a distance between the second sides of adjacent ones of the sensing pixels, an event detection distance in the second direction corresponds to a distance between the first sides of the adjacent ones of the sensing pixels, and the sensing pixels are repetitively arranged on the sensing pixel array in the first direction and the second direction in a staggered form.

In some embodiments, the first sides are point-symmetrical to each other with respect to a center of the inclined N-polygon shape in the ones of the sensing pixels, the second sides are point-symmetrical to each other with respect to the center of the inclined N-polygon shape in the ones of the sensing pixels, a light receiving element of the ones of the sensing pixels is located in a center region that includes the center of the inclined N-polygon shape, and a location of the light receiving element in the inclined N-polygon shape is the same for all of the ones of the sensing pixels.

In some embodiments, a light receiving element of the ones of the sensing pixels is located in a center region that includes the center of the inclined N-polygon shape, a location of the light receiving element in the inclined N-polygon shape differs according to the ones of the sensing pixels.

It is noted that aspects of the invention described with respect to one embodiment, may be incorporated in a different embodiment although not specifically described relative thereto. That is, all embodiments and/or features of any embodiment can be combined in any way and/or combination. These and other objects and/or aspects of the present invention are explained in detail in the specification set forth below.

### BRIEF DESCRIPTION OF THE DRAWINGS

Illustrative, non-limiting example embodiments will be more clearly understood from the following detailed description in conjunction with the accompanying drawings.

FIG. 1 is a block diagram illustrating a dynamic vision sensor according to some embodiments.

FIG. 2 is a diagram illustrating an arrangement of sensing pixels on a sensing pixel array included in the dynamic vision sensor of FIG. 1.

FIG. 3A is a diagram illustrating some embodiments in which a light receiving element is located in each of the sensing pixels of FIG. 2.

FIG. 3B is a diagram illustrating some embodiments in which a light receiving element is located in each of the sensing pixels of FIG. 2.

FIG. 3C is a diagram illustrating some embodiments in which a light receiving element is located in each of the sensing pixels of FIG. 2.

FIG. 4 is a flowchart illustrating a process in which the dynamic vision sensor of FIG. 1 detects a first direction motion.

FIGS. 5A and 5B are diagrams for describing why the dynamic vision sensor of FIG. 1 has higher resolution in a first direction than a conventional dynamic vision sensor.

FIG. 6 is a flowchart illustrating a process in which the dynamic vision sensor of FIG. 1 detects a second direction motion.

FIGS. 7A and 7B are diagrams for describing why the dynamic vision sensor of FIG. 1 has higher resolution in a second direction than a conventional dynamic vision sensor.

FIG. 8 is a flowchart illustrating a process in which the dynamic vision sensor of FIG. 1 detects a third direction motion.

FIG. 9 is a block diagram illustrating a motion recognition device according to some embodiments.

FIG. 10 is a diagram illustrating an example of a dynamic vision sensor included in the motion recognition device of FIG. 9.

FIG. 11 is a diagram illustrating some embodiments in which the motion recognition device of FIG. 9 recognizes a user motion.

FIG. 12 is a block diagram illustrating an electronic device according to some embodiments.

FIG. 13 is a diagram illustrating some embodiments in which the electronic device of FIG. 12 is implemented as a smart phone.

FIG. 14 is a flowchart illustrating a process in which the electronic device of FIG. 12 performs an unlocking operation using a motion recognition device.

FIG. 15 is a block diagram illustrating a computing system according to some embodiments.

### DETAILED DESCRIPTION OF THE EMBODIMENTS

Various example embodiments will be described more fully with reference to the accompanying drawings, in which some example embodiments are shown. The present inventive concept may, however, be embodied in many different forms and should not be construed as limited to the embodiments set forth herein. Rather, these embodiments are provided so that this disclosure will be thorough and complete, and will fully convey the scope of the present inventive concept to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

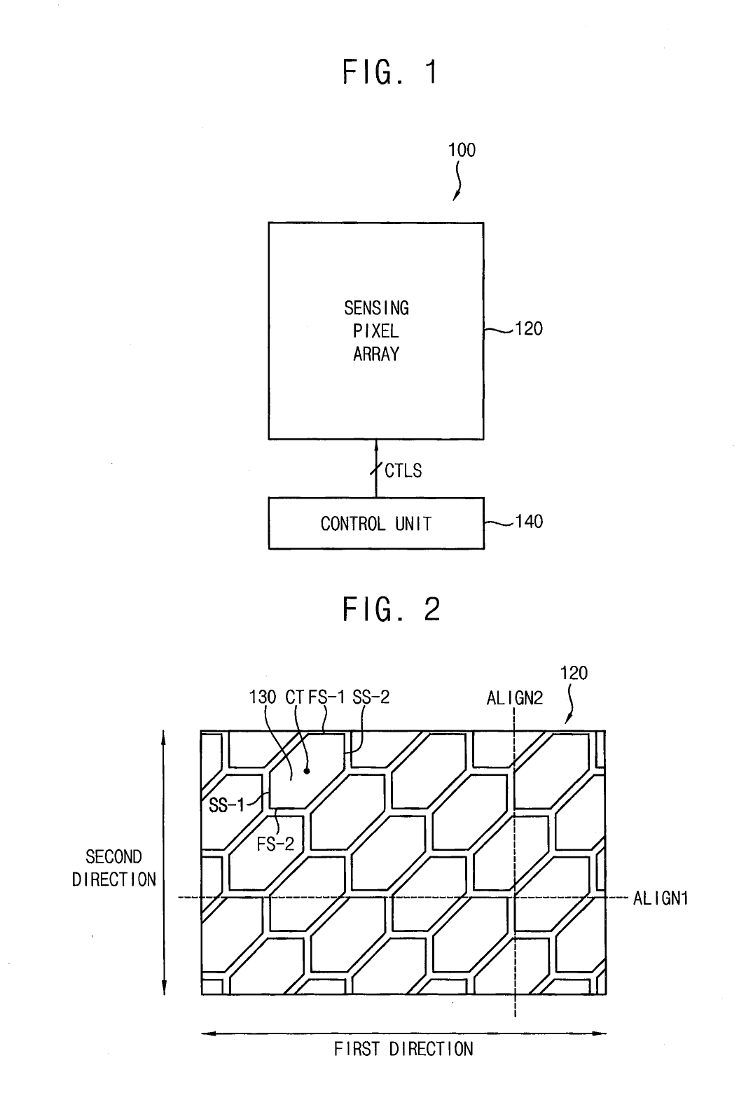

FIG. 1 is a block diagram illustrating a dynamic vision sensor according to example embodiments. FIG. 2 is a diagram illustrating an arrangement of sensing pixels on a sensing pixel array included in the dynamic vision sensor of FIG. 1.

Referring to FIGS. 1 and 2, the dynamic vision sensor 100 may include a sensing pixel array 120 and a control unit 140. Here, the dynamic vision sensor 100 may detect a portion of the subject in which a motion occurs, and may output events related thereto by a unit of time-stamp. Thus, the dynamic vision sensor 100 may be referred to as a time-stamp based sensor and/or an event based sensor.

The sensing pixel array 120 may include a plurality of sensing pixels 130 each detecting a change of light intensity and to output an event related thereto by a unit of time-stamp. Here, the events output by a unit of time stamp may include at least one selected among time information related to when the change of light intensity occurs and location information related to where the change of light intensity occurs. Thus, an electronic device (e.g., a motion recognition device, etc) including the dynamic vision sensor 100 may generate motion information based on the events that the sensing pixels 130 of the sensing pixel array 120 output by a unit of time-stamp. The control unit 140 may provide the sensing pixel array 120 with a plurality of control signals CTLS to control the sensing pixel array 120. As illustrated in FIG. 2, each sensing pixel 130 of the sensing pixel array 120 may have an inclined N-polygon shape, where N is an even number greater than or equal to 4. In addition, each sensing pixel 130 may include first sides FS-1 and FS-2 extended in a first direction (i.e., indicated as FIRST DIRECTION) that stand opposite to each other in a second direction (i.e., indicated as SECOND DIRECTION) in a staggered form and second sides SS-1 and SS-2 extended in the second direction that stand opposite to each other in the first direction in a staggered form. Here, the first direction may be perpendicular to the second direction. On this basis, the dynamic vision sensor 100 may output the events by a unit of time-stamp based on the first sides FS-1 and FS-2 and the second sides SS-1 and SS-2 of the sensing pixels 130 included in the sensing pixel array 120.

The sensing pixels 130 may be repetitively arranged on the sensing pixel array 120 in the first and second directions in a staggered form. Although it is illustrated in FIG. 2 that each sensing pixel 130 has an inclined hexagon shape, a shape of each sensing pixel 130 is not limited to a hexagon shape. That is, each sensing pixel 130 may have an N-polygon shape that includes the first sides FS-1 and FS-2 extended in the first direction that stand opposite to each other in the second direction in a staggered form and the second sides SS-1 and SS-2 extended in the second direction that stand opposite to each other in the first direction in a staggered form, where N is an even number greater than or equal to 4. In some embodiments, the first direction may correspond to an X-axis direction of the sensing pixel array 120, and the second direction may correspond to a Y-axis direction of the sensing pixel array 120. In this case, an X-axis direction motion may be determined as a first direction motion, and a Y-axis direction motion may be determined as a second direction motion. In some embodiments, the first direction may correspond to a direction that is rotated by a predetermined angle from the X-axis direction of the sensing pixel array 120, and the second direction may correspond to a direction that is rotated by a predetermined angle from the Y-axis direction of the sensing pixel array 120. In this case, an X-axis direction motion may be determined by considering the predetermined angle based on a first direction motion, and a Y-axis direction motion may be determined by considering the predetermined angle based on a second direction motion.

In addition, as illustrated in FIG. 2, a length of the first sides FS-1 and FS-2 may be the same as a length of the second sides SS-1 and SS-2 in each sensing pixel 130. In some embodiments, a length of the first sides FS-1 and FS-2 may be different from a length of the second sides SS-1 and SS-2 in each sensing pixel 130. Further, as illustrated in FIG. 2, the first sides FS-1 and FS-2 may be point-symmetrical to each other with respect to a center CT of the inclined N-polygon shape, and the second sides SS-1 and SS-2 may also be point-symmetrical to each other with respect to the center CT of the inclined N-polygon shape in each sensing pixel 130. In other words, since the first sides FS-1 and FS-2 extended in the first direction stand opposite to each other in the second direction in a staggered form, an upper first side FS-1 may overlap a lower first side FS-2 when the upper first side FS-1 is rotated by 180 degrees with respect to the center CT of the inclined N-polygon shape in each sensing pixel 130. Similarly, since the second sides SS-1 and SS-2 extended in the second direction stand opposite to each other in the first direction in a staggered form, a left second side SS-1 may overlap a right second side SS-2 when the left second side SS-1 is rotated by 180 degrees with respect to the center CT of the inclined N-polygon shape in each sensing pixel 130. Hence, in the sensing pixel array 120, the first sides FS-1 and FS-2 of the sensing pixels 130 may be aligned in the first direction (i.e., indicated as ALIGN1), and the second sides SS-1 and SS-2 of the sensing pixels 130 may be aligned in the second direction (i.e., indicated as ALIGN2).

Each sensing pixel 130 may include a light receiving element. Here, the light receiving element may be a photodiode. However, the light receiving element is not limited thereto. In some embodiments, the light receiving element of each sensing pixel 130 may be located in a center region that includes the center CT of the inclined N-polygon shape, and a location of the light receiving element in the inclined N-polygon shape may be the same for all sensing pixels 130. In some embodiments, the light receiving element of each sensing pixel 130 may be located in a center region that includes the center CT of the inclined N-polygon shape, and a location of the light receiving element in the inclined N-polygon shape may differ according to the sensing pixels 130. In some embodiments, the light receiving element of each sensing pixel 130 may be located near the first sides FS-1 and FS-2 of each sensing pixel 130 or near the second sides SS-1 and SS-2 of each sensing pixel 130, and a location of the light receiving element in the inclined N-polygon shape may be the same for all sensing pixels 130. For example, for all sensing pixels 130, the light receiving element of each sensing pixel 130 may be located near the upper first side FS-1, near the lower first side FS-2, near the left second side SS-1, or near the right second side SS-2. In some embodiments, the light receiving element of each sensing pixel 130 may be located near the first sides FS-1 and FS-2 of each sensing pixel 130 or near the second sides SS-1 and SS-2 of each sensing pixel 130, and a location of the light receiving element in the inclined N-polygon shape may differ according to the sensing pixels 130. For example, the light receiving element of one sensing pixel 130 may be located near the upper first side FS-1, the light receiving element of another sensing pixel 130 may be located near the lower first side FS-2, the light receiving element of another sensing pixel 130 may be located near the left second side SS-1, and the light receiving element of another sensing pixel 130 may be located near the right second side SS-2.

As described above, the first sides FS-1 and FS-2 of the sensing pixels 130 are aligned in the first direction (i.e., indicated as ALIGN1) and the second sides SS-1 and SS-2 of the sensing pixels 130 are aligned in the second direction (i.e., indicated as ALIGN2) in the sensing pixel array 120. Therefore, an event detection distance of the dynamic vision sensor 100 in the first direction may correspond to a distance between the left second sides SS-1 and SS-1 of adjacent sensing pixels 130 (i.e., a distance between the left second side SS-1 of one sensing pixel 130 and the left second side SS-1 of another sensing pixel 130 that is adjacent the sensing pixel 130) or a distance between the right second sides SS-2 and SS-2 of adjacent sensing pixels 130 (i.e., a distance between the right second side SS-2 of one sensing pixel 130 and the right second side SS-2 of another sensing pixel 130 that is adjacent the sensing pixel 130). In addition, an event detection distance of the dynamic vision sensor 100 in the second direction may correspond to a distance between the upper first sides FS-1 and FS-1 of adjacent sensing pixels 130 (i.e., a distance between the upper first side FS-1 of one sensing pixel 130 and the upper first side FS-1 of another sensing pixel 130 that is adjacent the sensing pixel 130) or a distance between the lower first sides FS-2 and FS-2 of adjacent sensing pixels 130 (i.e., a distance between the lower first side FS-2 of one sensing pixel 130 and the lower first side FS-2 of another sensing pixel 130 that is adjacent the sensing pixel 130). Here, although an area of each sensing pixel 130 may be similar to an area of each conventional sensing pixel having a tetragon shape, the event detection distance of the dynamic vision sensor 100 in the first direction may be shorter than an event detection distance of a conventional dynamic vision sensor in the first direction, and the event detection distance of the dynamic vision sensor 100 in the second direction may be shorter than an event detection distance of the conventional dynamic vision sensor in the second direction. That is, the dynamic vision sensor 100 may have increased (or, improved) resolution while having a fixed (or, limited) size by including the sensing pixels 130 that are repetitively arranged on the sensing pixel array 120 in the first and second directions in a staggered form, where each sensing pixel 130 having the inclined N-polygon shape includes the first sides FS-1 and FS-2 extended in the first direction that stand opposite to each other in the second direction in a staggered form and the second sides SS-1 and SS-2 extended in the second direction that stand opposite to each other in the first direction in a staggered form.

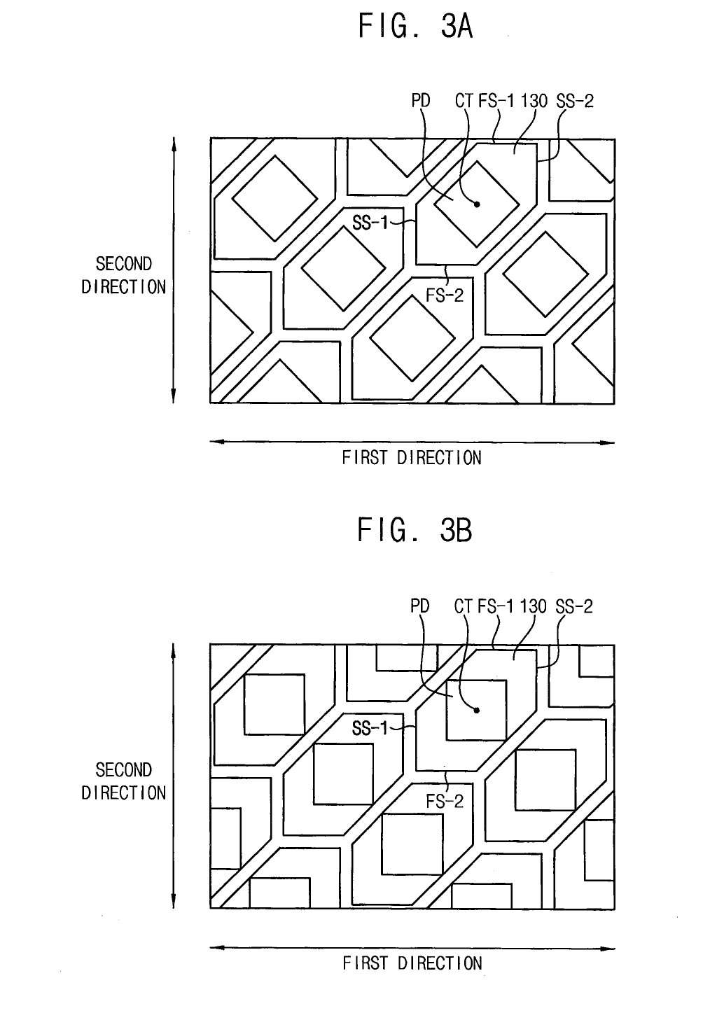

FIG. 3A is a diagram illustrating some embodiments in which a light receiving element is located in each of the sensing pixels of FIG. 2. FIG. 3B is a diagram illustrating some embodiments in which a light receiving element is located in each of the sensing pixels of FIG. 2. FIG. 3C is a diagram illustrating some embodiments in which a light receiving element is located in each of the sensing pixels of FIG. 2.

Referring to FIGS. 3A through 3C, the light receiving element PD may be located at various locations in the sensing pixels 130 included in the sensing pixel array 120. Here, the light receiving element PD may be a photodiode. However, the light receiving element PD is not limited thereto. As described above, since each sensing pixel 130 has the inclined N-polygon shape, the sensing pixels 130 may implement increased (or, improved) resolution of the dynamic vision sensor 100 although an area of each sensing pixel 130 (e.g., greater than or equal to 20 μm*20 μm) is the same as an area of each conventional sensing pixel having a tetragon shape.

In some embodiments, as illustrated in FIGS. 3A and 3B, the light receiving element PD of each sensing pixel 130 may be located in a center region that includes the center CT of the inclined N-polygon shape, and a location of the light receiving element PD in the inclined N-polygon shape may be the same for all sensing pixels 130. Thus, an event detection distance of the dynamic vision sensor 100 in the first direction (i.e., indicated as FIRST DIRECTION) may correspond to a distance between the left second sides SS-1 and SS-1 of adjacent sensing pixels 130 (i.e., a distance between the left second side SS-1 of one sensing pixel 130 and the left second side SS-1 of another sensing pixel 130 that is adjacent the sensing pixel 130) or a distance between the right second sides SS-2 and SS-2 of adjacent sensing pixels 130 (i.e., a distance between the right second side SS-2 of one sensing pixel 130 and the right second side SS-2 of another sensing pixel 130 that is adjacent the sensing pixel 130). In addition, an event detection distance of the dynamic vision sensor 100 in the second direction (i.e., indicated as SECOND DIRECTION) may correspond to a distance between the upper first sides FS-1 and FS-1 of adjacent sensing pixels 130 (i.e., a distance between the upper first side FS-1 of one sensing pixel 130 and the upper first side FS-1 of another sensing pixel 130 that is adjacent the sensing pixel 130) or a distance between the lower first sides FS-2 and FS-2 of adjacent sensing pixels 130 (i.e., a distance between the lower first side FS-2 of one sensing pixel 130 and the lower first side FS-2 of another sensing pixel 130 that is adjacent the sensing pixel 130). In some embodiments, the light receiving element PD of each sensing pixel 130 may be located in a center region that includes the center CT of the inclined N-polygon shape, and a location of the light receiving element PD in the inclined N-polygon shape may differ according to the sensing pixels 130. In this case, an event detection distance of the dynamic vision sensor 100 in the first direction and an event detection distance of the dynamic vision sensor 100 in the second direction may become shorter. However, more sensing pixels 130 should be considered together to detect the first direction motion and the second direction motion. For example, in FIGS. 3A and 3B, two rows of the sensing pixels 130 may be considered together to detect the first direction motion, and two columns of the sensing pixels 130 may be considered together to detect the second direction motion. On the other hand, when a location of the light receiving element PD in the inclined N-polygon shape differs according to the sensing pixels 130, at least three rows of the sensing pixels 130 may be considered together to detect the first direction motion, and at least three columns of the sensing pixels 130 may be considered together to detect the second direction motion.

In some embodiments, as illustrated in FIG. 3C, the light receiving element PD of each sensing pixel 130 may be located near the first sides FS-1 and FS-2 of each sensing pixel 130 or near the second sides SS-1 and SS-2 of each sensing pixel 130, and a location of the light receiving element PD in the inclined N-polygon shape may be the same for all sensing pixels 130. For example, for all sensing pixels 130, the light receiving element PD of each sensing pixel 130 may be located near the upper first side FS-1, near the lower first side FS-2, near the left second side SS-1, or near the right second side SS-2. In FIG. 3C, it is illustrated that the light receiving element PD of each sensing pixel 130 is located near the left second side SS-1 (or, near the lower first side FS-2). Thus, an event detection distance of the dynamic vision sensor 100 in the first direction may correspond to a distance between the left second sides SS-1 and SS-1 of adjacent sensing pixels 130 or a distance between the right second sides SS-2 and SS-2 of adjacent sensing pixels 130. In addition, an event detection distance of the dynamic vision sensor 100 in the second direction may correspond to a distance between the upper first sides FS-1 and FS-1 of adjacent sensing pixels 130 or a distance between the lower first sides FS-2 and FS-2 of adjacent sensing pixels 130. In some embodiments, the light receiving element PD of each sensing pixel 130 may be located near the first sides FS-1 and FS-2 of each sensing pixel 130 or near the second sides SS-1 and SS-2 of each sensing pixel 130, and a location of the light receiving element PD in the inclined N-polygon shape may differ according to the sensing pixels 130. In this case, as described above, more sensing pixels 130 should be considered together to detect the first direction motion and the second direction motion. For example, at least three rows of the sensing pixels 130 may be considered together to detect the first direction motion, and at least three columns of the sensing pixels 130 may be considered together to detect the second direction motion.

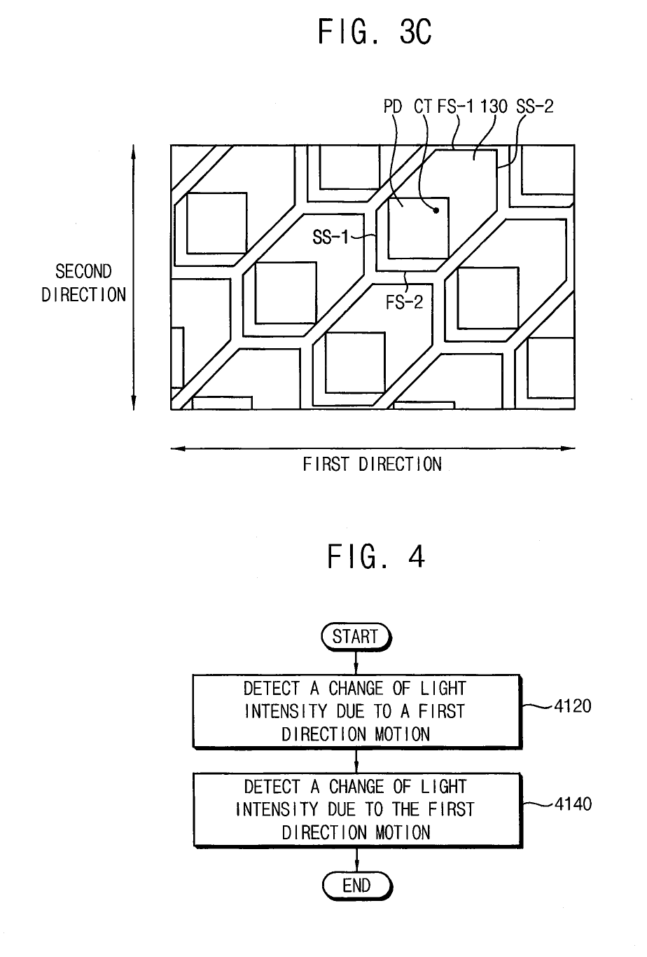

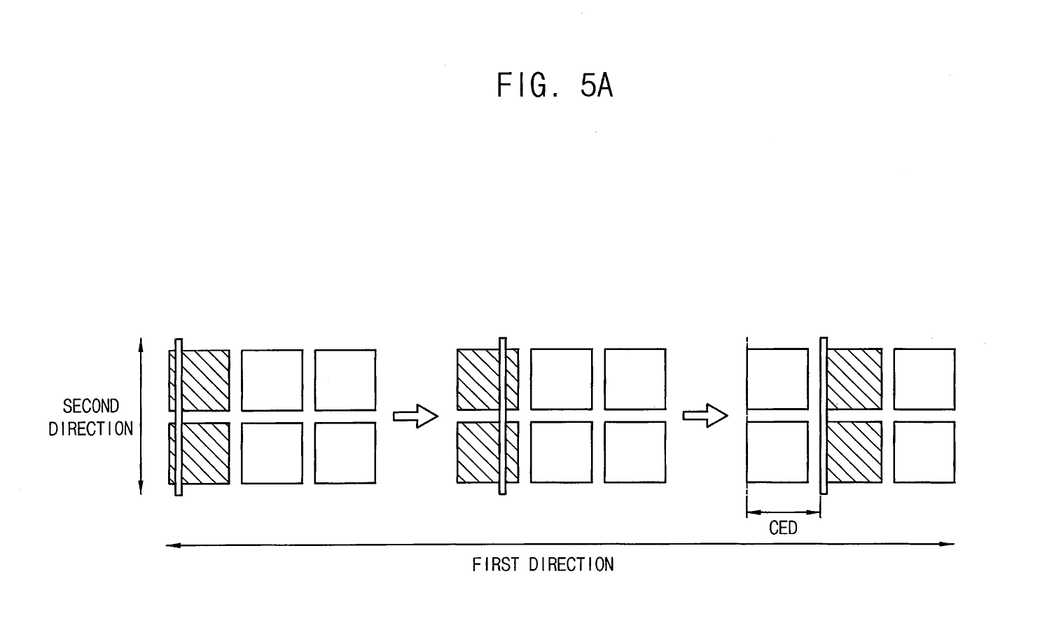

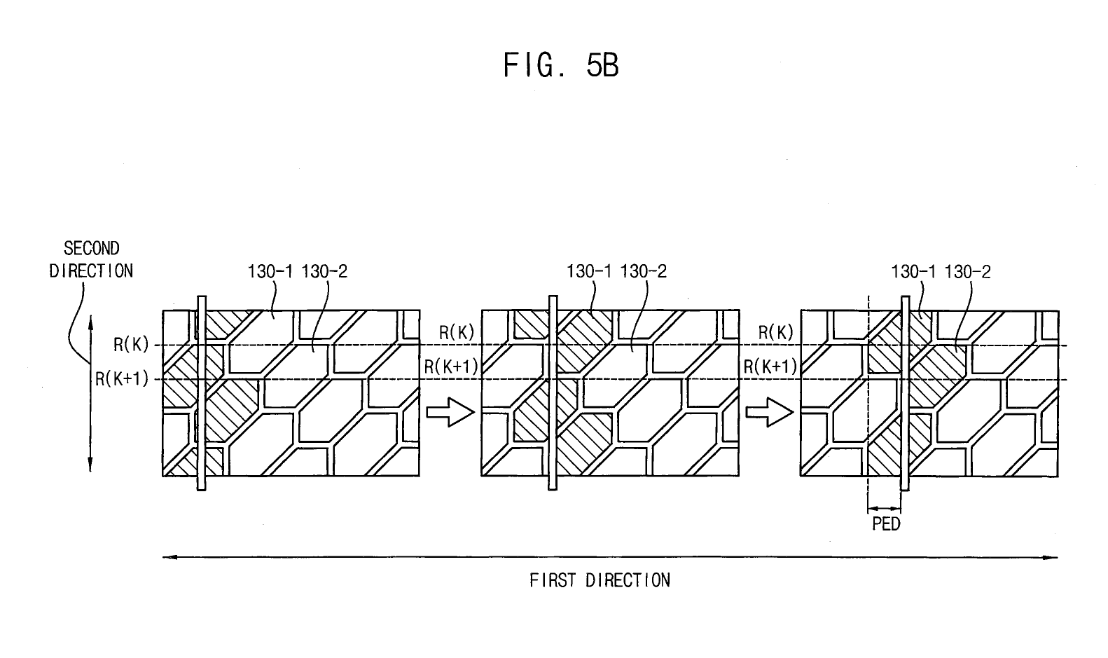

FIG. 4 is a flowchart illustrating a process in which the dynamic vision sensor of FIG. 1 detects a first direction motion. FIGS. 5A and 5B are diagrams for describing why the dynamic vision sensor of FIG. 1 has higher resolution in a first direction than a conventional dynamic vision sensor.

Referring to FIGS. 4 through 5B, the dynamic vision sensor 100 may detect the first direction motion based on the second sides SS-1 and SS-2 of the sensing pixels 130. In the dynamic vision sensor 100, a first sensing pixel 130-1 may detect a change of light intensity due to the first direction motion (block 4120). Subsequently, a second sensing pixel 130-2 that is adjacent the first sensing pixel 130-1 may detect a change of light intensity due to the first direction motion (block 4140). Here, an area of each conventional sensing pixel having a tetragon shape illustrated in FIG. 5A is substantially the same as an area of each sensing pixel 130 having an inclined hexagon shape illustrated in FIG. 5B.

As illustrated in FIG. 5A, each conventional sensing pixel may have a tetragon shape, where a light receiving element is located in the tetragon shape. Thus, in a conventional dynamic vision sensor, an event detection distance CED of the conventional dynamic vision sensor in the first direction may correspond to a distance between a left side of one conventional sensing pixel and a left side of another conventional sensing pixel that is adjacent the conventional sensing pixel in the first direction. On the other hand, as illustrated in FIG. 5B, each sensing pixel 130 may have an inclined hexagon shape, where a light receiving element PD is located in the inclined hexagon shape. Thus, in the dynamic vision sensor 100, an event detection distance PED of the dynamic vision sensor 100 in the first direction may correspond to a distance between the left second side SS-1 of the first sensing pixel 130-1 and the left second side SS-1 of the second sensing pixel 130-2 that is adjacent the first sensing pixel 130-1. That is, although an area of each sensing pixel 130 having an inclined hexagon shape illustrated in FIG. 5B is the same as an area of each conventional sensing pixel having a tetragon shape illustrated in FIG. 5A, the event detection distance PED of the dynamic vision sensor 100 in the first direction may be shorter than the event detection distance CED of the conventional dynamic vision sensor in the first direction. As a result, the dynamic vision sensor 100 may have increased (or, improved) resolution while having a fixed (or, limited) size. In FIG. 5B, it is illustrated that the first sensing pixel 130-1 constitutes a (k)th row R(k) and the second sensing pixel 130-2 constitutes a (k+1)th row R(k+1), where k is an integer greater than or equal to 1. This shows that the dynamic vision sensor 100 considers two rows of the sensing pixels 130 together to detect the first direction motion. However, as described above, when a location of the light receiving element PD in the inclined N-polygon shape differs according to the sensing pixels 130, a quantity of rows of the sensing pixels 130 considered together to detect the first direction motion may be increased.

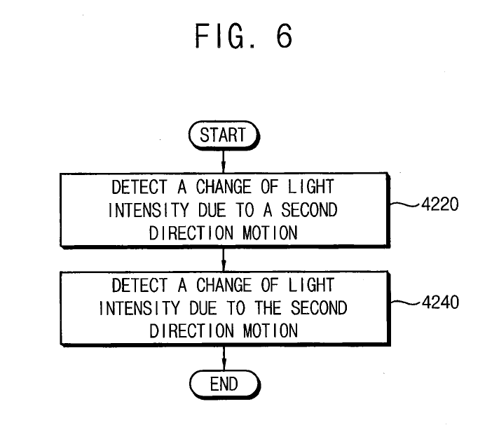

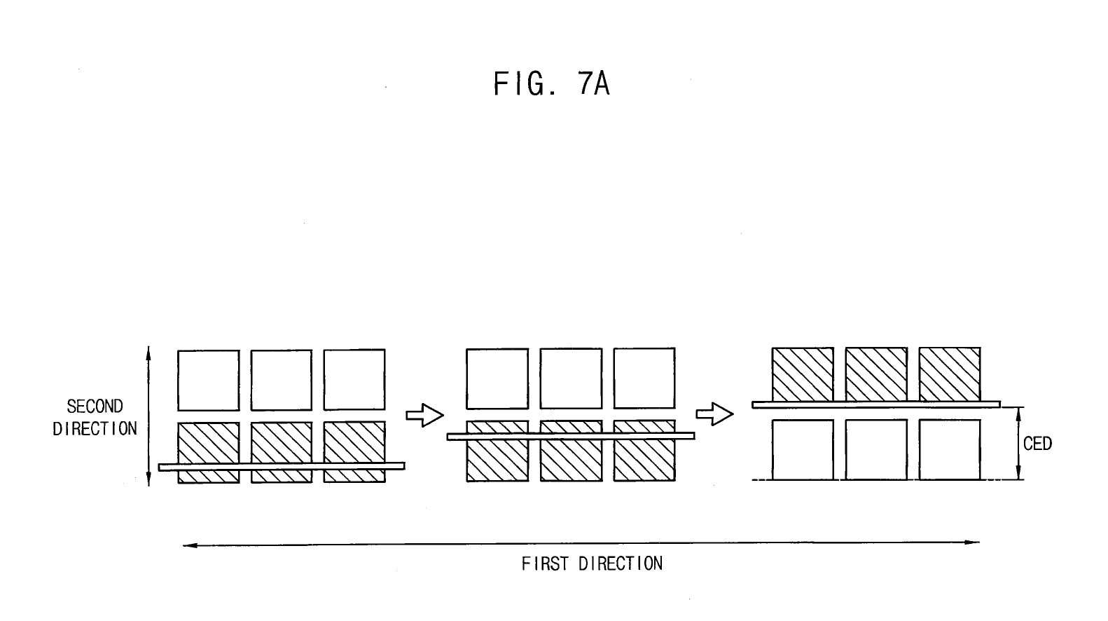

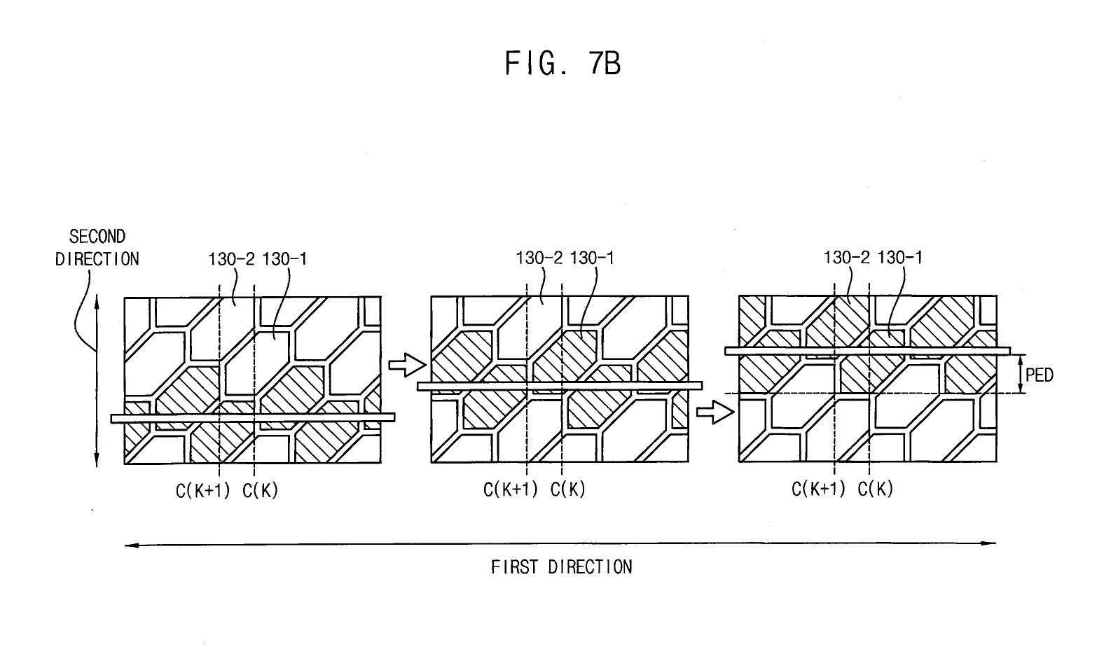

FIG. 6 is a flowchart illustrating a process in which the dynamic vision sensor of FIG. 1 detects a second direction motion. FIGS. 7A and 7B are diagrams for describing why the dynamic vision sensor of FIG. 1 has higher resolution in a second direction than a conventional dynamic vision sensor.

Referring to FIGS. 6 through 7B, the dynamic vision sensor 100 may detect the second direction motion based on the first sides FS-1 and FS-2 of the sensing pixels 130. In the dynamic vision sensor 100, a first sensing pixel 130-1 may detect a change of light intensity due to the second direction motion (block 4220). Subsequently, a second sensing pixel 130-2 that is adjacent the first sensing pixel 130-1 may detect a change of light intensity due to the second direction motion (block 4240). Here, an area of each conventional sensing pixel having a tetragon shape illustrated in FIG. 7A is substantially the same as an area of each sensing pixel 130 having an inclined hexagon shape illustrated in FIG. 7B.

As illustrated in FIG. 7A, each conventional sensing pixel may have a tetragon shape, where a light receiving element is located in the tetragon shape. Thus, in a conventional dynamic vision sensor, an event detection distance CED of the conventional dynamic vision sensor in the second direction may correspond to a distance between a lower side of one conventional sensing pixel and a lower side of another conventional sensing pixel that is adjacent the conventional sensing pixel in the second direction. On the other hand, as illustrated in FIG. 7B, each sensing pixel 130 may have an inclined hexagon shape, where a light receiving element PD is located in the inclined hexagon shape. Thus, in the dynamic vision sensor 100, an event detection distance PED of the dynamic vision sensor 100 in the second direction may correspond to a distance between the lower first side FS-2 of the first sensing pixel 130-1 and the lower first side FS-2 of the second sensing pixel 130-2 that is adjacent the first sensing pixel 130-1. That is, although an area of each sensing pixel 130 having an inclined hexagon shape illustrated in FIG. 7B is the same as an area of each conventional sensing pixel having a tetragon shape illustrated in FIG. 7A, the event detection distance PED of the dynamic vision sensor 100 in the second direction may be shorter than the event detection distance CED of the conventional dynamic vision sensor in the second direction. As a result, the dynamic vision sensor 100 may have increased (or, improved) resolution while having a fixed (or, limited) size. In FIG. 7B, it is illustrated that the first sensing pixel 130-1 constitutes a (k)th column C(k) and the second sensing pixel 130-2 constitutes a (k+1)th column C(k+1), where k is an integer greater than or equal to 1. This shows that the dynamic vision sensor 100 considers two columns of the sensing pixels 130 together to detect the second direction motion. However, as described above, when a location of the light receiving element PD in the inclined N-polygon shape differs according to the sensing pixels 130, a quantity of columns of the sensing pixels 130 considered together to detect the second direction motion may be increased.

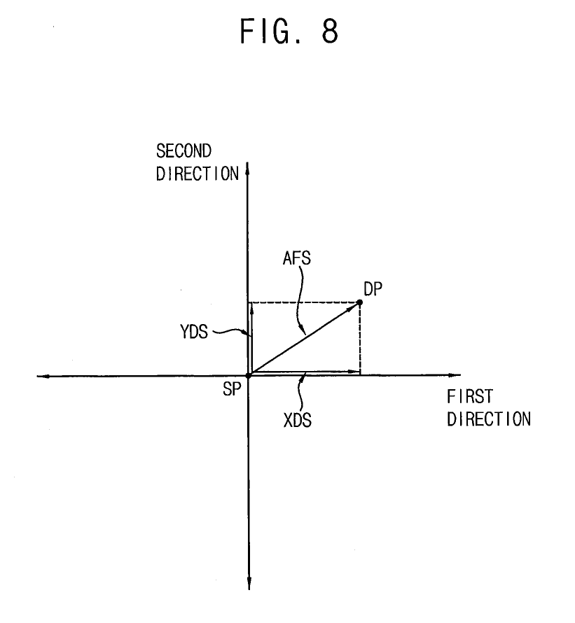

FIG. 8 is a flowchart illustrating a process in which the dynamic vision sensor of FIG. 1 detects a third direction motion.

Referring to FIG. 8, when a motion occurs from a first point SP to a second point DP on an imaging surface of the sensing pixel array 120 included in the dynamic vision sensor 100, the dynamic vision sensor 100 may detect a first direction motion and a second direction motion, and then may determine a third direction motion (i.e., a diagonal direction motion) based on the first direction motion and the second direction motion.

Specifically, as illustrated in FIG. 8, when the first direction motion and the second direction motion are detected by the dynamic vision sensor 100, a first motion vector XDS related to the first direction motion and a second motion vector YDS related to the second direction motion may be obtained. Subsequently, a third motion vector AFS related to the third direction motion between the first direction motion and the second direction motion may be obtained based on a vector operation between the first motion vector XDS related to the first direction motion and the second motion vector YDS related to the second direction motion. Thus, the dynamic vision sensor 100 may detect the third direction motion by detecting the first direction motion and the second direction motion. In some embodiments, the first direction may correspond to an X-axis direction of the sensing pixel array 120, and the second direction may correspond to a Y-axis direction of the sensing pixel array 120. In this case, an X-axis direction motion may be determined as the first direction motion, and a Y-axis direction motion may be determined as the second direction motion. In some embodiments, the first direction may correspond to a direction that is rotated by a predetermined angle from the X-axis direction of the sensing pixel array 120, and the second direction may correspond to a direction that is rotated by a predetermined angle from the Y-axis direction of the sensing pixel array 120. In this case, the X-axis direction motion may be determined by considering the predetermined angle based on the first direction motion, and the Y-axis direction motion may be determined by considering the predetermined angle based on the second direction motion.

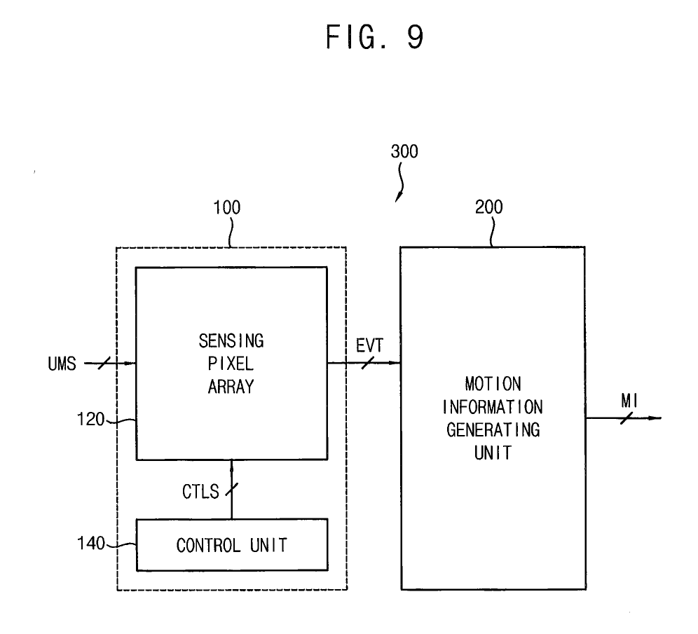

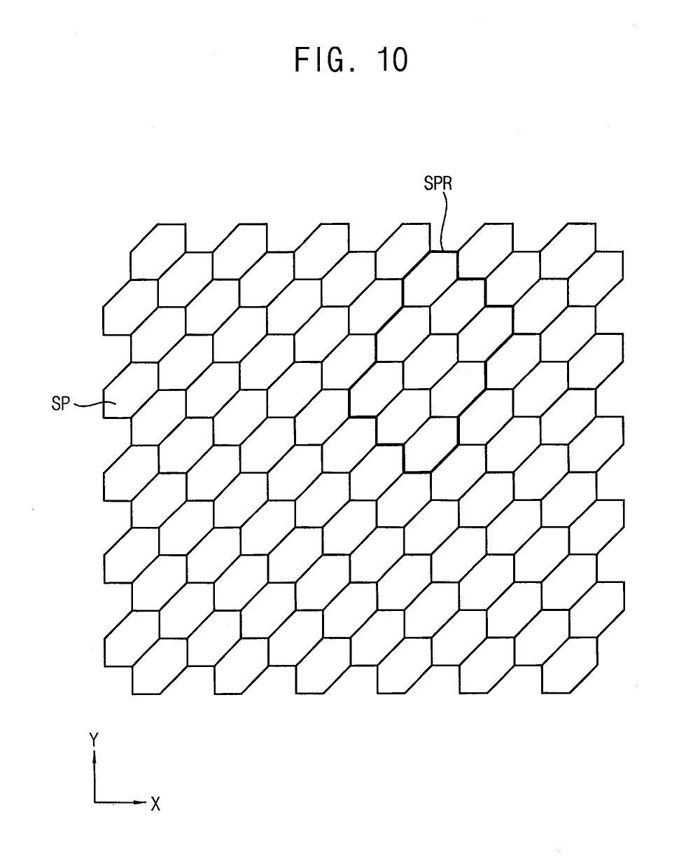

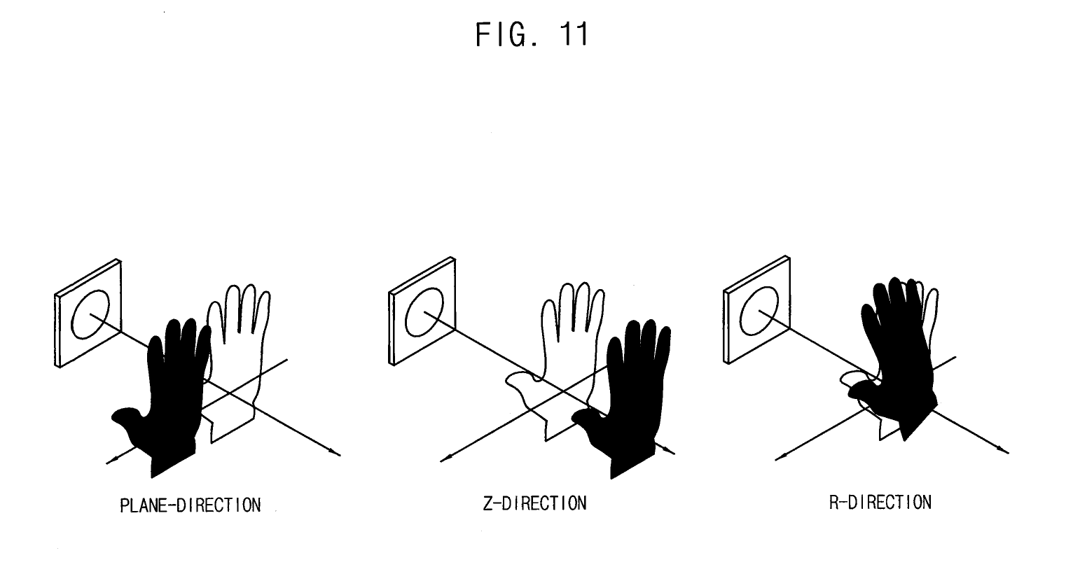

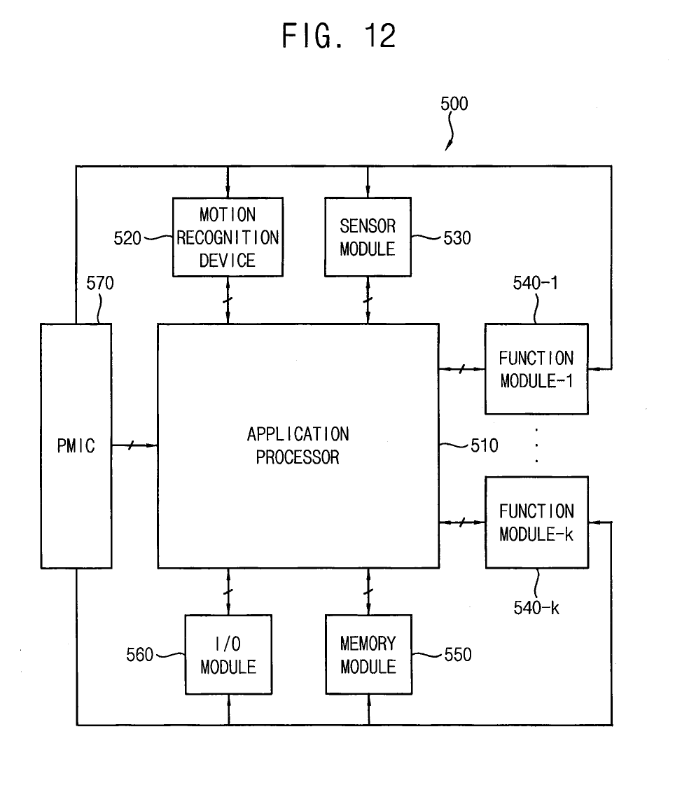

FIG. 9 is a block diagram illustrating a motion recognition device according to some embodiments. FIG. 10 is a diagram illustrating an example of a dynamic vision sensor included in the motion recognition device of FIG. 9. FIG. 11 is a diagram illustrating some embodiments in which the motion recognition device of FIG. 9 recognizes a user motion.

Referring to FIGS. 9 through 11, the motion recognition device 300 may include a sensing pixel array 120, a control unit 140, and a motion information generating unit 200. Here, the sensing pixel array 120 and the control unit 140 may constitute the dynamic vision sensor 100. As described above, the dynamic vision sensor 100 may detect a portion of the subject in which a motion occurs, and may output events EVT related thereto by a unit of time-stamp. Thus, the dynamic vision sensor 100 may be referred to as a time-stamp based sensor or an event based sensor.

The sensing pixel array 120 may include a plurality of sensing pixels SP each detecting a change of light intensity UMS to output an event EVT related thereto by a unit of time-stamp. For example, when the change of light intensity UMS occurs, each sensing pixel SP may compare the change of light intensity UMS with a predetermined threshold value, and then may output the event EVT if the change of light intensity UMS is larger than the predetermined threshold value. Here, the event EVT may include at least one selected among time information related to when the change of light intensity UMS occurs and location information related to where the change of light intensity UMS occurs. The control unit 140 may provide the sensing pixel array 120 with a plurality of control signals CTLS to control the sensing pixel array 120. Here, each sensing pixel SP of the sensing pixel array 120 may have an inclined N-polygon shape, where N is an even number greater than or equal to 4. In addition, each sensing pixel SP of the sensing pixel array 120 may include first sides extended in a first direction that stand opposite to each other in a second direction in a staggered form and second sides extended in the second direction that stand opposite to each other in the first direction in a staggered form. In some embodiments, the first direction may be perpendicular to the second direction. Hence, the dynamic vision sensor 100 may output the events EVT based on the first sides and the second sides of the sensing pixels SP included in the sensing pixel array 120.

As illustrated in FIG. 10, the sensing pixels SP may be repetitively arranged on the sensing pixel array 120 in the first direction (e.g., an X-axis direction) and the second direction (e.g., a Y-axis direction) in a staggered form. Here, each sensing pixel SP may include a light receiving element (e.g., a photodiode). In some embodiments, the sensing pixels SP may be grouped into a plurality of sensing fields SPR to obtain information related to temporal and/or spatial relations between a plurality of changes of light intensity UMS. Although it is illustrated in FIG. 10 that a sensing field SPR has an inclined 3×3 matrix shape, a shape of the sensing field SPR is not limited thereto. For example, the sensing field SPR may have an inclined q×r matrix shape, where q and r are integers greater than 1. In addition, a length of the first sides may be the same as a length of the second sides in each sensing pixel SP. In some embodiments, a length of the first sides may be different from a length of the second sides in each sensing pixel SP. Further, the first sides may be point-symmetrical to each other with respect to a center of the inclined N-polygon shape, and the second sides may also be point-symmetrical to each other with respect to the center of the inclined N-polygon shape in each sensing pixel SP. Thus, in the sensing pixel array 120, the first sides of the sensing pixels SP may be aligned in the first direction, and the second sides of the sensing pixels SP may be aligned in the second direction. In some embodiments, the first direction may correspond to the X-axis direction of the sensing pixel array 120, and the second direction may correspond to the Y-axis direction of the sensing pixel array 120. In some embodiments, the first direction may correspond to a direction that is rotated by a predetermined angle from the X-axis direction of the sensing pixel array 120, and the second direction may correspond to a direction that is rotated by a predetermined angle from the Y-axis direction of the sensing pixel array 120.

The motion information generating unit 200 may receive the event EVT output by a unit of time-stamp from the sensing pixel array 120, and then may generate motion information MI by analyzing a motion region based on the event EVT. Specifically, the motion information generating unit 200 may obtain (or, generate) a first motion vector related to a first direction motion and a second motion vector related to a second direction motion based on the event EVT. For example, assuming that the first direction corresponds to the X-axis direction and the second direction corresponds to the Y-axis direction, the motion information generating unit 200 may obtain the first motion vector related to the X-axis direction motion and the second motion vector related to the Y-axis direction motion. Thus, the motion information generating unit 200 may obtain a third motion vector related to a third direction motion (i.e., a diagonal direction motion) between the first direction motion and the second direction motion based on a vector operation between the first motion vector related to the first direction motion and the second motion vector related to the second direction motion. For example, assuming that the first direction corresponds to the X-axis direction and the second direction corresponds to the Y-axis direction, the motion information generating unit 200 may obtain a motion vector related any direction motion between the X-axis direction motion and the Y-axis direction motion. Subsequently, the motion information generating unit 200 may generate the motion information MI corresponding to a user motion by analyzing the first motion vector related to the first direction motion, the second motion vector related to the second direction motion, and the third motion vector related to the third direction motion using a predetermined algorithm.

As illustrated in FIG. 11, the user motion may be analyzed in spatial coordinates (i.e., X-Y-Z coordinates) with respect to the imaging surface of the sensing pixel array 120. Here, assuming that a coordinate plane that is parallel to the imaging surface of the sensing pixel array 120 is an X-Y plane, a user motion on the X-Y plane including an upper-lower direction (e.g., Y-axis direction) motion, a left-right direction (e.g., X-axis direction) motion, and a diagonal direction motion may be referred to as a plane-direction motion (i.e., indicated as PLANE-DIRECTION). In addition, a user motion perpendicular to the X-Y plane (i.e., the imaging surface of the sensing pixel array 120) may be referred to as a Z-axis direction motion (i.e., indicated as Z-DIRECTION). Further, a user motion rotating on the X-Y plane may be referred to as a rotational-direction motion (i.e., indicated as R-DIRECTION). Therefore, the motion information generating unit 200 may generate the motion information MI indicating the plane-direction motion, the Z-axis direction motion, and/or the rotational-direction motion by analyzing the first motion vector related to the first direction motion, the second motion vector related to the second direction motion, and the third motion vector related to the third direction motion using the predetermined algorithm. However, since the user motion described above is an example, a kind of the user motion is not limited thereto.

As described above, the dynamic vision sensor 100 may include the sensing pixels SP that are repetitively arranged on the sensing pixel array 120 in the first and second directions in a staggered form, where each sensing pixel SP has the inclined N-polygon shape, where N is an even number greater than or equal to 4. In addition, each sensing pixel SP may include the first sides extended in the first direction that stand opposite to each other in the second direction in a staggered form and the second sides extended in the second direction that stand opposite to each other in the first direction in a staggered form. Thus, an event detection distance of the dynamic vision sensor 100 in the first direction may correspond to a distance between the left second sides of adjacent sensing pixels SP or a distance between the right second sides of adjacent sensing pixels SR In addition, an event detection distance of the dynamic vision sensor 100 in the second direction may correspond to a distance between the upper first sides of adjacent sensing pixels SP or a distance between the lower first sides of adjacent sensing pixels SR Here, although an area of each sensing pixel SP is the same as an area of each conventional sensing pixel having a tetragon shape, the event detection distance of the dynamic vision sensor 100 in the first direction may be shorter than an event detection distance of a conventional dynamic vision sensor in the first direction, and the event detection distance of the dynamic vision sensor 100 in the second direction may be shorter than an event detection distance of the conventional dynamic vision sensor in the second direction. As a result, the dynamic vision sensor 100 may have increased (or, improved) resolution while having a fixed (or, limited) size. In addition, the motion recognition device 300 including the dynamic vision sensor 100 may accurately recognize the user motion.

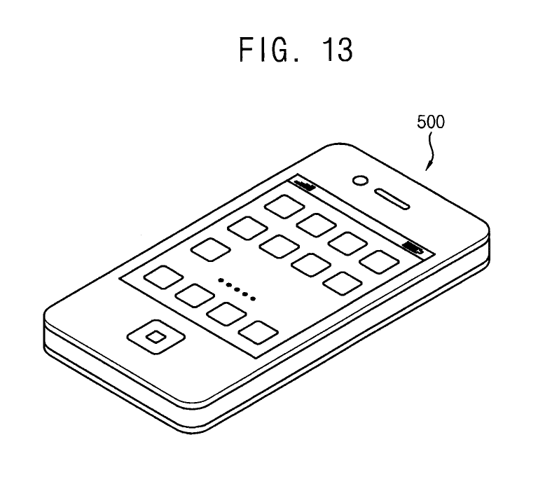

FIG. 12 is a block diagram illustrating an electronic device according to some embodiments. FIG. 13 is a diagram illustrating some embodiments in which the electronic device of FIG. 12 is implemented as a smart phone.

Referring to FIGS. 12 and 13, the electronic device 500 may include an application processor 510, a motion recognition device 520, at least one sensor module 530, a plurality of function modules 540-1 through 540-k, a memory module 550, an input/output (I/0) module 560, and a power management integrated circuit (PMIC) 570. Here, the motion recognition device 520 may correspond to the motion recognition device 300 of FIG. 9. As illustrated in FIG. 13, the electronic device 500 may be implemented as the smart phone. However, the electronic device 500 is not limited thereto. For example, the electronic device 500 may be implemented as a computer, a laptop, a digital camera, a video camcorder, a cellular phone, a smart phone, a video phone, a smart pad, a tablet PC, an MP3 player, etc.

The application processor 510 may control an overall operation of the electronic device 500. That is, the application processor 510 may control the motion recognition device 520, the sensor module 530, the function modules 540-1 through 540-k, the memory module 550, the I/O module 560, the power management integrated circuit 570, etc. In some embodiments, the application processor 510 may include a main processor that operates based on a first clock signal (i.e., a high performance processor) and a sub processor that operates based on a second clock signal of which an operating frequency is lower than an operating frequency of the first clock signal (i.e., a low performance processor). In an active mode of the electronic device 500, only the main processor or both of the main processor and the sub processor may operate in the application processor 510. In a sleep mode of the electronic device 500, only the sub processor may operate in the application processor 510. For example, in the active mode of the electronic device 500, only the main processor or both of the main processor and the sub processor may control the motion recognition device 520, the sensor module 530, the function modules 540-1 through 540-k, the memory module 550, the I/O module 560, the power management integrated circuit 570, etc. On the other hand, in the sleep mode of the electronic device 500, only the sub processor may control some components (e.g., the motion recognition device 520, the sensor module 530, etc) of the electronic device 500,

The motion recognition device 520 may recognize a user motion. To this end, the motion recognition 520 may include a sensing pixel array, a control unit, and a motion information generating unit. The sensing pixel array may include a plurality of sensing pixels each detecting a change of light intensity to output an event related thereto by a unit of time-stamp. The control unit may control the sensing pixel array. The motion information generating unit may generate motion information by analyzing a motion region based on the events output by a unit of time-stamp. Here, the sensing pixel array and the control unit may constitute a dynamic vision sensor. In the sensing pixel array, each sensing pixel may have an inclined N-polygon shape, where N is an even number greater than or equal to 4. In addition, each sensing pixel may include first sides extended in a first direction that stand opposite to each other in a second direction in a staggered form and second sides extended in the second direction that stand opposite to each other in the first direction in a staggered form. Here, the first direction may be perpendicular to the second direction. Therefore, the dynamic vision sensor may have increased (or, improved) resolution while having a fixed (or, limited) size by including the sensing pixels that are repetitively arranged on the sensing pixel array in the first and second directions in a staggered form, where each sensing pixel has the inclined N-polygon shape. In addition, the motion recognition device 520 including the dynamic vision sensor may accurately recognize the user motion. Since these are described above, duplicated description will not be repeated.

The sensor module 530 may perform various sensing operations. Here, the sensor module 530 may include a gyro sensor module that measures a rotating angular speed, an acceleration sensor module that measures a speed and a momentum, a geomagnetic field sensor module that acts as a compass, a barometer sensor module that measures an altitude, a gesture-proximity-illumination sensor module that performs various operations such as a motion recognition, a proximity detection, a illumination measurement, etc, a temperature-humidity sensor module that measures a temperature and a humidity, and a grip sensor module that determines whether the electronic device 500 is gripped by a user. However, a kind of the sensor module 530 is not limited thereto. The function modules 540-1 through 540-k may perform various functions of the electronic device 500. For example, the electronic device 500 may include a communication module that performs a communication function (e.g., code division multiple access (CDMA) module, long term evolution (LTE) module, radio frequency (RF) module, ultra wideband (UWB) module, wireless local area network (WLAN) module, worldwide interoperability for microwave access (WIMAX) module, etc), a camera module that performs a camera function, etc. In some embodiments, the electronic device 500 may further include a global positioning system (GPS) module, a microphone (MIC) module, a speaker module, etc. However, a kind of the function modules 540-1 through 540-k included in the electronic device 500 is not limited thereto.

The memory module 550 may store data for operations of the electronic device 500. In some embodiments, the memory module 550 may be included in the application processor 510. For example, the memory module 550 may include a volatile semiconductor memory device such as a dynamic random access memory (DRAM) device, a double data rate synchronous dynamic random access memory (DDR SDRAM) device, a static random access memory (SRAM) device, a mobile DRAM, etc, and/or a non-volatile semiconductor memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, etc. In some example embodiments, the memory module 550 may further include a solid state drive (SSD), a hard disk drive (HDD), a CD-ROM, etc. The I/O module 560 may include a display module that performs a display function, a touch panel module that performs a touch sensing function, etc.

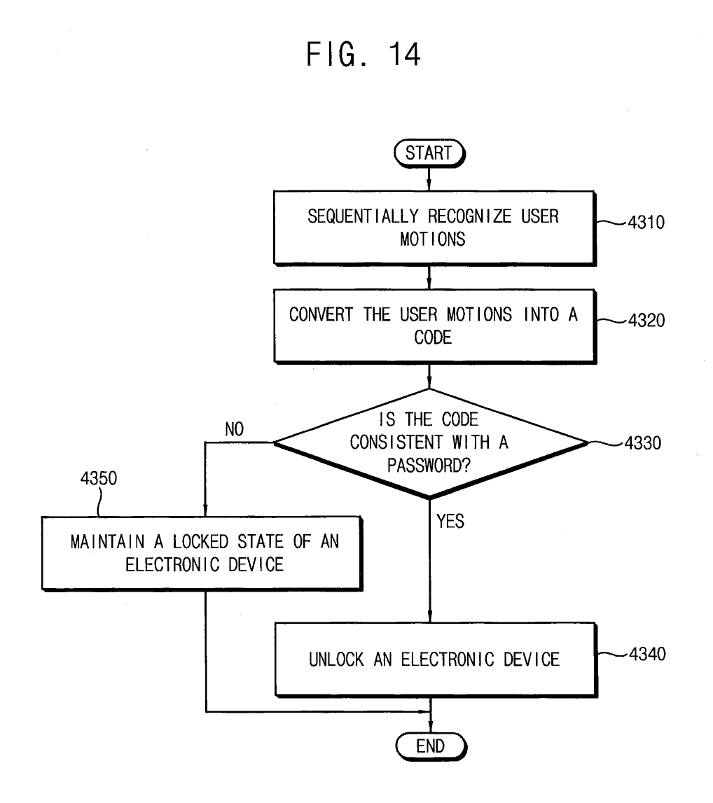

FIG. 14 is a flowchart illustrating a process in which the electronic device of FIG. 12 performs an unlocking operation using a motion recognition device according to some embodiments disclosed herein.

Referring to FIG. 14, the electronic device 500 may perform the unlocking operation using the motion recognition device 520. Specifically, the electronic device 500 may sequentially recognize user motions (block 4310), and then may convert the user motions into a code (block 4320). In other words, the electronic device 500 may code the user motions. Subsequently, the electronic device 500 may check whether the code is consistent with a predetermined password (block 4330). Here, when the code is consistent with the predetermined password, the electronic device 500 may be unlocked (block 4340). On the other hand, when the code is inconsistent with the predetermined password, a locked state of the electronic device 500 may be maintained (block 4350). In an example embodiment, the electronic device 500 may check whether the code is consistent with the predetermined password by comparing sequences and/or timings of the code with sequences and/or timings of the predetermined password. In another example embodiment, the electronic device 500 may check whether the code is consistent with the predetermined password by performing Dynamic Programming (DP) matching. In some embodiments, the electronic device 500 may check whether the code is consistent with the predetermined password by using Hidden Markov Model (HMM). However, methods of comparing the code with the predetermined password are not limited thereto.

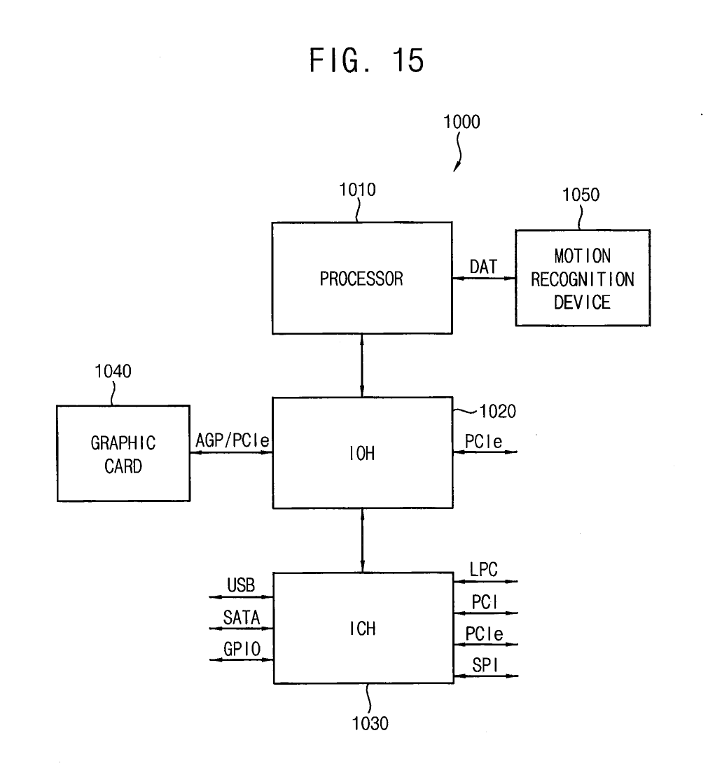

FIG. 15 is a block diagram illustrating a computing system according to some embodiments.

Referring to FIG. 15, the computing system 1000 may include a processor 1010, an input/output hub (IOH) 1020, an I/O controller hub (ICH) 1030, a graphics card 1040, and a motion recognition device 1050. Here, the motion recognition device 1050 may correspond to the motion recognition device 300 of FIG. 9.

The processor 1010 performs various computing functions. For example, the processor 1010 may be a microprocessor, a central process unit (CPU), etc. In some embodiments, the processor 1010 may include a single core or multiple cores such as a dual-core processor, a quad-core processor, a hexa-core processor, etc. The processor 1010 may further include an internal or external cache memory. The I/O hub 1020 may manage data transfer operations between the processor 1010 and devices such as the graphics card 1040. The I/O hub 1020 may be coupled to the processor 1010 based on various interfaces. For example, the interface between the processor 1010 and the I/O hub 1020 may be a front side bus (FSB), a system bus, a HyperTransport, a lightning data transport (LDT), a QuickPath interconnect (QPI), a common system interface (CSI), etc. Further, the I/O hub 1020 may provide various interfaces with the devices. For example, the I/O hub 1020 may provide an accelerated graphics port. (AGP) interface, a peripheral component interface-express (PCIe), a communications streaming architecture (CSA) interface, etc.

The graphics card 1040 may be coupled to the I/O hub 1020 via AGP or PCIe for controlling a display device (not shown) to display an image. The graphics card 1040 may include an internal processor for processing image data. In some embodiments, the I/O hub 1020 may include an internal graphics device instead of the graphics card 1040. Here, the graphics device included in the I/O hub 1020 may be referred to as integrated graphics. Further, the I/O hub 1020 including the internal memory controller and the internal graphics device may be referred to as a graphics and memory controller hub (GMCH). The I/O controller hub 1030 may perform data buffering and interface arbitration operations to efficiently operate various system interfaces. The I/O controller hub 1030 may be coupled to the I/O hub 1020 via an internal bus such as a direct media interface (DMI), a hub interface, an enterprise Southbridge interface (ESI), PCIe, etc. The I/O controller hub 1030 may interface with peripheral devices. For example, the I/O controller hub 1030 may provide a universal serial bus (USB) port, a serial advanced technology attachment (SATA) port, a general purpose input/output (GPIO), a low pin count (LPC) bus, a serial peripheral interface (SPI), PCI, PCIe, etc.

The motion recognition device 1050 may recognize a user motion. To this end, the motion recognition 1050 may include a sensing pixel array, a control unit, and a motion information generating unit. The sensing pixel array may include a plurality of sensing pixels each detecting a change of light intensity to output an event related thereto by a unit of time-stamp. The control unit may control the sensing pixel array. The motion information generating unit may generate motion information by analyzing a motion region based on the events output by a unit of time-stamp. Here, the sensing pixel array and the control unit may constitute a dynamic vision sensor. In the sensing pixel array, each sensing pixel may have an inclined N-polygon shape, where N is an even number greater than or equal to 4. In addition, each sensing pixel may include first sides extended in a first direction that stand opposite to each other in a second direction in a staggered form and second sides extended in the second direction that stand opposite to each other in the first direction in a staggered form. Here, the first direction may be perpendicular to the second direction. Therefore, the dynamic vision sensor may have increased (or, improved) resolution while having a fixed (or, limited) size by including the sensing pixels that are repetitively arranged on the sensing pixel array in the first and second directions in a staggered form, where each sensing pixel has the inclined N-polygon shape. In addition, the motion recognition device 1050 including the dynamic vision sensor may accurately recognize the user motion. Since these are described above, duplicated description will not be repeated. In some example embodiments, the computing system 1000 may be a personal computer, a server computer, a workstation, a laptop, etc.

The present inventive concept may be applied to a dynamic vision sensor and an electronic device including the dynamic vision sensor. For example, the present inventive concept may be applied to a computer, a laptop, a digital camera, a camcorder, a cellular phone, a smart phone, a video phone, a smart pad, a tablet PC, an MP3 player, a navigation system, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A dynamic vision sensor, comprising:
a sensing pixel array including a plurality of sensing pixels, ones of which are configured to detect a change of light intensity and to output an event by a unit of time-stamp responsive to detecting the change of light intensity; and
a control unit that is configured to control the sensing pixel array,
wherein ones of the plurality of sensing pixels have an inclined N-polygon shape, where N is an even number greater than or equal to 4, and
wherein the ones of the plurality of sensing pixels include first sides extended in a first direction that stand opposite to each other in a second direction in a staggered form and second sides extended in the second direction that stand opposite to each other in the first direction in a staggered form, the first direction being perpendicular to the second direction.

2. The sensor of claim 1, wherein the event includes at least one event that is selected among time information related to when the change of light intensity occurs and location information related to where the change of light intensity occurs.

3. The sensor of claim 2, wherein an event detection distance in the first direction corresponds to a distance between the second sides of adjacent ones of the plurality of sensing pixels, and
wherein an event detection distance in the second direction corresponds to a distance between the first sides of the adjacent ones of the plurality of sensing pixels.

4. The sensor of claim 1, wherein the plurality of sensing pixels are repetitively arranged on the sensing pixel array in the first direction and the second direction in a staggered form.

5. The sensor of claim 4, wherein the first sides are point-symmetrical to each other with respect to a center of the inclined N-polygon shape in the ones of the plurality of sensing pixels, and
wherein the second sides are point-symmetrical to each other with respect to the center of the inclined N-polygon shape in the ones of the plurality of sensing pixels.

6. The sensor of claim 5, wherein a light receiving element of the ones of the plurality of sensing pixels is located in a center region that includes the center of the inclined N-polygon shape, and a location of the light receiving element in the inclined N-polygon shape is the same for all of the ones of the plurality of sensing pixels.

7. The sensor of claim 5, wherein a light receiving element of the ones of the plurality of sensing pixels is located in a center region that includes the center of the inclined N-polygon shape, and a location of the light receiving element in the inclined N-polygon shape differs according to the ones of the plurality of sensing pixels.

8. The sensor of claim 5, wherein a light receiving element of the ones of the plurality of sensing pixels is located closer to one of the first sides than it is to a different one of the first sides or closer to one of the second sides than it is to a different one of the second sides, and a location of the light receiving element in the inclined N-polygon shape is the same for all of the ones of the plurality of sensing pixels.

9. The sensor of claim 5, wherein a light receiving element of the ones of the plurality of sensing pixels is located closer to one of the first sides than it is to a different one of the first sides or closer to one of the second sides than it is to a different one of the second sides, and a location of the light receiving element in the inclined N-polygon shape differs according to the plurality of sensing pixels.

10. A motion recognition device, comprising:
a sensing pixel array including a plurality of sensing pixels, ones of the plurality of sensing pixels configured to detect a change of light intensity and to output an event by a unit of time-stamp responsive to the detected change of light intensity;
a control unit configured to control the sensing pixel array; and
a motion information generating unit configured to generate motion information by analyzing a motion region based on the event,
wherein each of the sensing pixels has an inclined N-polygon shape, where N is an even number greater than or equal to 4, and
wherein the ones of the plurality of sensing pixels include first sides extended in a first direction that stand opposite to each other in a second direction in a staggered form and second sides extended in the second direction that stand opposite to each other in the first direction in a staggered form, the first direction being perpendicular to the second direction.

11. The device of claim 10, wherein the event includes at least one event that is selected among time information related to when the change of light intensity occurs and location information related to where the change of light intensity occurs.

12. The device of claim 11, wherein an event detection distance in the first direction corresponds to a distance between the second sides of adjacent ones of the plurality of sensing pixels, and
wherein an event detection distance in the second direction corresponds to a distance between the first sides of the adjacent ones of the plurality of sensing pixels.

13. The device of claim 10, wherein the motion information generating unit obtains a first motion vector related to a first direction motion and a second motion vector related to a second direction motion by analyzing the motion region.

14. The device of claim 13, wherein the motion information generating unit obtains a third motion vector related to a third direction motion between the first direction motion and the second direction motion based on a vector operation between the first motion vector and the second motion vector.

15. The device of claim 14, wherein the motion information generating unit generates the motion information corresponding to a user motion by analyzing the first motion vector, the second motion vector, and the third motion vector using a predetermined algorithm.

16. A dynamic vision sensor, comprising:
a sensing pixel array including a plurality of sensing pixels, ones of the plurality of sensing pixels being configured to detect a change of light intensity and to output an event responsive to detecting the change of light intensity; and
a control unit that is configured to control the sensing pixel array,
wherein ones of the plurality of sensing pixels have an inclined N-polygon shape, where N is an even number greater than or equal to 4, and
wherein the ones of the plurality of sensing pixels include first sides extended in a first direction that stand opposite to each other in a second direction in a staggered form and second sides extended in the second direction that stand opposite to each other in the first direction in a staggered form, the first direction being perpendicular to the second direction.

17. The sensor of claim 16, wherein the detected change comprises a rate of change event corresponding to the detected change over a time interval unit,
wherein the at least one event is selected from time information and location information,
wherein the time information corresponds to when the change of light intensity occurs, and wherein the location information corresponds to where the change of light intensity occurs.

18. The sensor of claim 16, wherein an event detection distance in the first direction corresponds to a distance between the second sides of adjacent ones of the plurality of sensing pixels,
wherein an event detection distance in the second direction corresponds to a distance between the first sides of the adjacent ones of the plurality of sensing pixels, and
wherein the plurality of sensing pixels are repetitively arranged on the sensing pixel array in the first direction and the second direction in a staggered form.

19. The sensor of claim 18, wherein the first sides are point-symmetrical to each other with respect to a center of the inclined N-polygon shape in the ones of the plurality of sensing pixels,
wherein the second sides are point-symmetrical to each other with respect to the center of the inclined N-polygon shape in the ones of the plurality of sensing pixels, and
wherein a light receiving element of the ones of the plurality of sensing pixels is located in a center region that includes the center of the inclined N-polygon shape, and a location of the light receiving element in the inclined N-polygon shape is the same for all of the ones of the plurality of sensing pixels.

20. The sensor of claim 18, wherein the first sides are point-symmetrical to each other with respect to a center of the inclined N-polygon shape in the ones of the plurality of sensing pixels,
wherein the second sides are point-symmetrical to each other with respect to the center of the inclined N-polygon shape in the ones of the plurality of sensing pixels, and
wherein a light receiving element of the ones of the plurality of sensing pixels is located in a center region that includes the center of the inclined N-polygon shape, and a location of the light receiving element in the inclined N-polygon shape differs according to the ones of the plurality of sensing pixels.
